(19) United States
(12) Patent Application Publication
(10) Pub. No.: US 2017/0077105 A1
(43) Pub. Date: Mar. 16, 2017

(54) SEMICONDUCTOR DEVICE

(71) Applicant: KABUSHIKI KAISHA TOSHIBA, Tokyo (JP)

(72) Inventors: Akira HOKAZONO, Kawasaki Kanagawa (JP); Shigeru KAWANAKA, Yokohama Kanagawa (JP)

(73) Assignee: KABUSHIKI KAISHA TOSHIBA, Tokyo (JP)

(21) Appl. No.: 15/012,486

(22) Filed: Feb. 1, 2016

(30) Foreign Application Priority Data
Sep. 11, 2015 (JP) 2015-180106

(51) Int. Cl. H01L 27/11; H01L 23/528; H01L 29/06

(52) U.S. Cl. CPC H01L 27/1104; H01L 29/0649; H01L 23/528

(57) ABSTRACT

According to an embodiment, a semiconductor device, includes: a first region of an n-type conductive layer; a second region of a p-type conductive layer on the first region; a first TFET having an n-type drain region formed in the second region; a second TFET provided adjacent to the first TFET and of a TFET having an n-type drain region formed in the second region; and an insulating film formed between the drain region of the first TFET and the drain region of the second TFET, and reaching the first region.

### CROSS-REFERENCE TO RELATED APPLICATIONS

This application is based upon and claims the benefit of priority from the prior Japanese Patent Application No. 2015-180106, filed on Sep. 11, 2015; the entire contents of which are incorporated herein by reference.

### FIELD

Embodiments described herein relate generally to a semiconductor device.

### BACKGROUND

Conventionally, an SRAM (Static Radom Access Memory) using six MOSFETs (Metal Oxide Semiconductor Field Effect Transistors) has been in widespread use. Presently, to reduce the retention failure due to leakage of electric charges during standby of the SRAM, it is suggested to constitute the SRAM using TFET (Tunnel Field Effect Transistors).

The TFET can operate at lower voltage as compared with the MOSFET, and has characteristics such as a small leakage current in an off-state and so on. On the other hand, the drain current is small in an on-state and the current is saturated at a relatively low applied voltage, so that the driver ability is low to cause a reduction in reading speed as a storage device. Therefore, a technique using two MOSFETs for a read port is suggested in order to improve the reading characteristics.

However, since the TFET has diffusion layers of the drain and the source which are formed by different kinds of doping, it is impossible to operate the SRAM using the TFET in the manufacturing method by the same layout and process as those of the MOSFET.

### BRIEF DESCRIPTION OF THE DRAWINGS

FIG. 1 is a circuit diagram of a semiconductor device according to a first embodiment;

FIG. 2 is a layout chart of the semiconductor device according to the first embodiment;

FIG. 3A and FIG. 3B are a layout chart and a cross-sectional view of the semiconductor device according to the first embodiment;

FIG. 4A and FIG. 4B are a layout chart and a cross-sectional view of the semiconductor device according to the first embodiment;

FIGS. 5A through 5D are cross-sectional views illustrating manufacturing processes of the semiconductor device according to the first embodiment;

FIG. 6A and FIG. 6B are a layout chart and a cross-sectional view of a semiconductor device according to a second embodiment;

FIGS. 7A through 7D are cross-sectional views illustrating manufacturing processes of the semiconductor device according to the second embodiment;

FIG. 8 is a circuit diagram of a semiconductor device according to a third embodiment;

FIG. 9 is a layout chart of the semiconductor device according to the third embodiment;

FIG. 10A and FIG. 10B are a layout chart and a cross-sectional view of the semiconductor device according to the third embodiment; and

FIGS. 11A through 11D are cross-sectional views illustrating manufacturing processes of the semiconductor device according to the third embodiment.

### DETAILED DESCRIPTION

According to an embodiment, a semiconductor device, includes: a first region of an n-type conductive layer; a second region of a p-type conductive layer on the first region; a first TFET having an n-type drain region formed in the second region; a second TFET provided adjacent to the first TFET having an n-type drain region formed in the second region; and an insulating film formed between the drain region of the first TFET and the drain region of the second TFET, and reaching the first region.

Embodiments will now be explained with reference to the accompanying drawings. The present invention is not limited to the embodiments.

### First Embodiment

A semiconductor device according to a first embodiment is configured such that an SRAM includes six TFETs by physical division at an element isolation region between a drain of a driver transistor made of an nTFET and a drain of a transfer transistor made of an nTFET. Its layout and process will be described below in more detail.

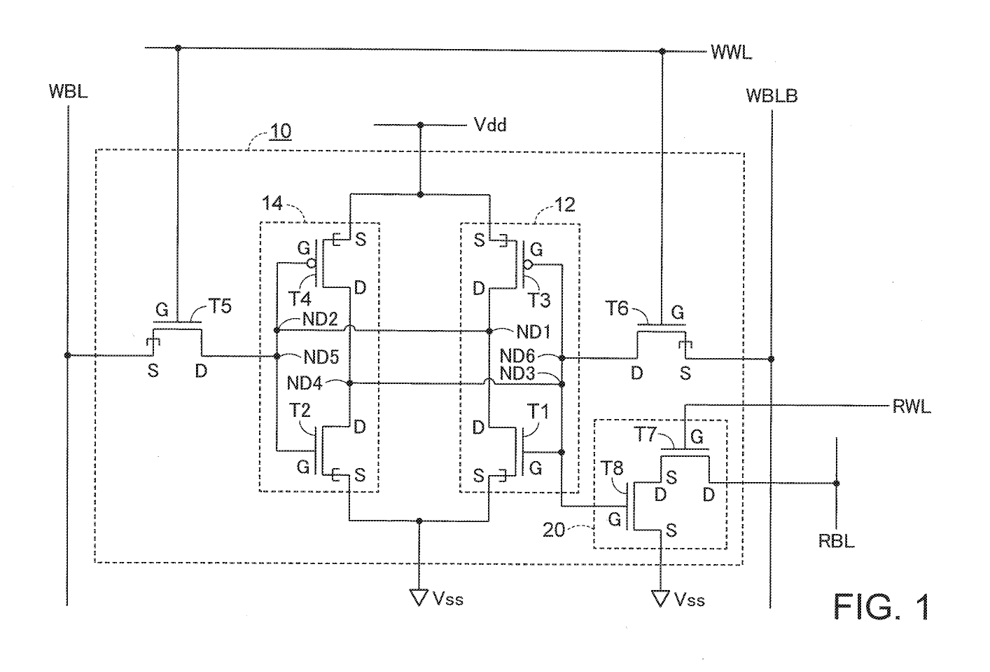

FIG. 1 is a circuit diagram illustrating the configuration of a memory cell 10 of the SRAM being the semiconductor device according to this embodiment. The memory cell 10 according to this embodiment includes inverter circuits 12, 14, a data read circuit 20, and transfer transistors T5, T6.

The inverter circuit 12 includes a driver transistor T1 made of an nTFET, and a load transistor T3 made of a pTFET. Here, the nTFET means an n-type tunnel transistor having a source region of a p-type conductive layer and a drain region of an n-type conductive layer. On the other hand, the pTFET means a p-type tunnel transistor having a source region of an n-type conductive layer and a drain region of a p-type conductive layer.

A drain of the driver transistor Ti and a drain of the load transistor T3 are connected to each other. Similarly, a gate of the driver transistor T1 and a gate of the load transistor T3 are also connected to each other. Further, a source of the driver transistor T1 is grounded and a source of the load transistor T3 is connected to a power supply Vdd.

The inverter circuit 14 includes a driver transistor T2 and a load transistor T4. This inverter circuit 14 also has the same configuration as that of the inverter circuit 12. More specifically, a drain of the driver transistor T2 and a drain of the load transistor T4 are connected to each other, and a gate of the driver transistor T2 and a gate of the load transistor T4 are also connected to each other. Further, a source of the driver transistor T2 is grounded and a source of the load transistor T4 is connected to the power supply Vdd.

A node ND1 between the drain of the driver transistor T1 and the drain of the load transistor T3 is connected to a node ND2 between the gate of the driver transistor T2 and the gate of the load transistor T4. A node ND3 between the gate of the driver transistor T1 and the gate of the load transistor T3 is connected to a node ND4 between the drain of the driver transistor T2 and the drain of the load transistor T4. More specifically, an output of the inverter circuit 12 is connected to an input of the inverter circuit 14, and an output of the inverter circuit 14 is connected to an input of the inverter circuit 12. By connecting the inverter circuits 12, 14 as described above, a flip-flop circuit is constituted.

The transfer transistor T5 is made of an nTFET having a gate connected to a write word line WWL and a source connected to a write bit line WBL. Further, a drain of the transfer transistor T5 is connected to a node ND5 between the gate of the driver transistor 12 and the gate of the load transistor T4.

Similarly, the transfer transistor T6 is made of an nTFET having a gate connected to the write word line WWL and a source connected to a write bit line WBLB. Further, a drain of the transfer transistor T6 is connected to a node ND6 between the gate of the driver transistor T1 and the gate of the load transistor T3. The write bit line WBLB is a bit line into which a signal made by inverting an input to the write bit line WBL is inputted.

The write word line WWL is a word line that applies voltage for turning on the transfer transistors T5, T6, and the write bit lines WBL, WBLB are bit lines that apply voltages for storing states to the driver transistors. In other words, the transfer transistors T5, T6 are transistors that are turned on by the voltage applied from the write word line WWL and output signals inputted thereinto from the write bit lines WBL, WBLB to the nodes ND5, ND6 respectively. As a result, the driver transistors T2, T1 store the states of the voltages applied to the write bit lines WBL, WBLB when the transfer transistors T5, T6 are turned on.

The data read circuit 20 includes read transistors T7, T8. The read transistor T7 has a gate connected to a read word line RWL, a drain connected to a read bit line RBL, and a source connected to a drain of the read transistor T8. The read transistor T8 has a gate connected to the node ND6, namely, the gates of the driver transistor T1 and the load transistor T3, the drain connected to the source of the read transistor T7, and a source grounded. In this embodiment, the read transistors T7, T8 are made of n-type MOSFETs.

The above is the description about the configuration of the memory cell 10 according to this embodiment, and the operation of the memory cell 10 will be described below. First of all, write processing will be described. In the write processing, voltage at Low level, for example, a ground potential Vss is applied to the read word line RWL. This brings the read transistor T7 connected to the read bit line RWB into an off-state.

In the write processing, High voltage, for example, the power supply voltage Vdd is applied to the write word line WWL. This turns on the transfer transistors T5, T6 having the gates connected to the write word line WWL. In this state, when Low voltage is applied to the write bit line WBL with the node ND5 being in a High state, the voltage level of the node ND5 becomes Low from High to turn on the load transistor T4 and turn off the driver transistor T2. On the other hand, High voltage is applied to the write bit line WBLB, so that the voltage level of the node ND6 becomes High to turn on the driver transistor T1 and turn off the load transistor T3.

When the voltage levels of the nodes ND5, ND6 are decided as described above, the states of the inverter circuits 12, 14 are held because the voltage Vdd is applied from the power supply even if the voltage level of the write word line WWL becomes Low, and the states of the nodes ND5, ND6 are also held. Then, reading the states of the nodes ND5, ND6 makes it possible to read data on a bit-by-bit basis.

In the case where the write word line WWL is High, when High voltage is applied to the write bit line WBL and Low voltage is applied to the write bit line WBLB, the operations of the inverter circuits 12, 14 are reverse to those in the above-described case, so that the voltage level of the node ND5 becomes High and the voltage level of the node ND6 becomes Low. In other words, only if the level of voltage applied to the write word line WWL is High, the states of the nodes ND5, ND6 are decided by the voltages applied to the write bit lines WBL, WBLB, and when the level of voltage applied to the write word line WWL is Low, the states of the nodes ND5, ND6 are held.

Next, read processing will be described. In the read processing, voltage at Low level, for example, the ground potential Vss is applied to the write word line WWL. This turns off the transfer transistors T5, T6.

When reading, voltage at High level, for example, the power supply voltage Vdd is applied to the read word line RWL. This turns on the read transistor T7 having the gate connected to the read word line RWL. In this state, when the voltage level of the node ND6 is in a High state, the read transistor T8 turns on, so that the voltage of the read bit line RBL is decreased. On the other hand, when the node ND6 is in a Low state, the read transistor T8 turns off, so that no change occurs in the voltage of the read bit line RBL and a pre-charged high state is held.

Sensing the voltage of the read bit line RBL as described above makes it possible to read the data held in the memory cell 10. The read transistors T7, T8 are made of nMOS transistors high in drive capability to enable the data read circuit 20 to perform the data read operation at a high speed. As described above, the memory cell 10 according to this embodiment includes the six transistors T1 to T6 for data hold and the two transistors T7, T8 for data read.

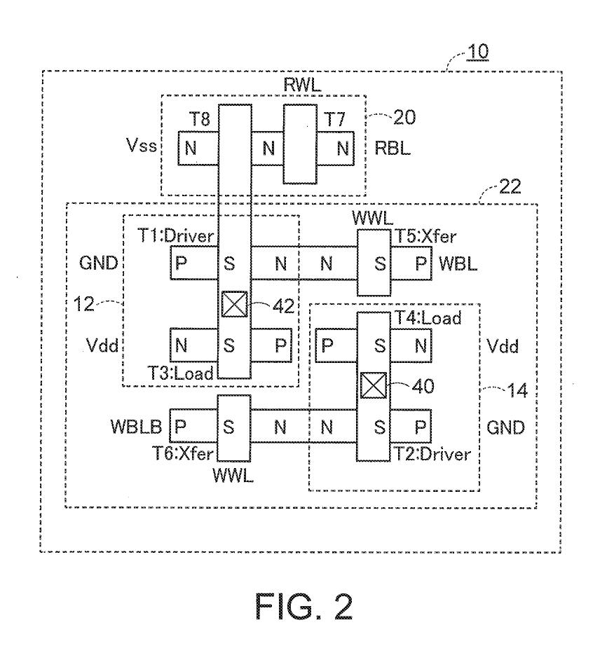

Next, the layout and process when actually designing the memory cell 10 will be described. FIG. 2 is a diagram illustrating the layout of a semiconductor constituted by the circuit diagram illustrated in FIG. 1. As illustrated in FIG. 2, the memory cell 10 includes the data read circuit 20 and a data holding circuit 22. The data holding circuit 22 includes a flip-flop circuit made of the inverter circuits 12, 14, and the transfer transistors T5, T6. The functions of the components are as described in FIG. 1 and therefore will be omitted.

The data read circuit 20 includes two nMOS transistors. The read transistor T7 has a drain region connected to the read bit line RBL and a gate region connected to the read word line RWL. The read transistor T8 has a source region grounded and a gate region shared with gate regions of the driver transistor T1 and the load transistor T3. The read transistors T7, T8 are MOSFETs whose source regions and drain regions are n-type, and therefore can be formed while sharing the source region of the read transistor T7 and the drain region of the read transistor T8.

On the other hand, for the transistors T1 to T6 made of TFETs, the configuration of the gate can be designed as in, the conventional manner, but the source region and the drain region are different in type of the conductive layers and therefore cannot be designed as in the conventional manner. Hereinafter, a concrete layout will be described using FIG. 1 and FIG. 2. Note that, in the drawings, a symbol S in the gate region means that the side with S is the source region.

The driver transistor T1 has a p-type conductive layer being the source region grounded, an n-type conductive layer being the drain region shared with the drain region of the transfer transistor T5, and a gate region shared with the gate regions of the load transistor T3 and the read transistor T8.

The load transistor T3 has an n-type conductive layer being the source region connected to the power supply Vdd, a p-type conductive layer being the drain region electrically connected (not illustrated) to the drain region of the driver transistor T1, and a gate region shared with the gate region of the driver transistor T1. Further, the drain regions of the driver transistor T1 and the load transistor T3 are connected (not illustrated) to gate regions of the driver transistor T2 and the load transistor T4 via a contact 40.

The above is the description about the layout of the inverter circuit 12. Next, the driver transistor T2 and the load transistor T4 of the inverter circuit 14 will be described. The driver transistor T2 has a p-type conductive layer being the source region grounded, an n-type conductive layer being the drain region shared with the drain region of the transfer transistor T6, and the gate region shared with the load transistor T4.

The load transistor T4 has an n-type conductive layer being the source region connected to the power supply Vdd, a p-type conductive layer being the drain region electrically connected (not illustrated) to the drain region of the driver transistor T2, and the gate region shared with the gate region of the driver transistor T2. Further, the drain regions of the driver transistor T2 and the load transistor T4 are connected (not illustrated) to the gate regions of the driver transistor T1 and the load transistor T3 via a contact 42.

The above is the description about the layout of the inverter circuit 14. Next, the transfer transistors T5, T6 will be described. The transfer transistor T5 has a p-type conductive layer being the source region connected to the write bit line WBL, an n-type conductive layer being the drain region shared with the drain region of the driver transistor T1, and the gate region connected to the write word line WWL. Further, the transfer transistor T6 similarly has a p-type conductive layer being the source region connected to the write bit line WBLB, an n-type conductive layer being the drain region shared with the drain region of the driver transistor T2, and the gate region connected to the write word line WWL.

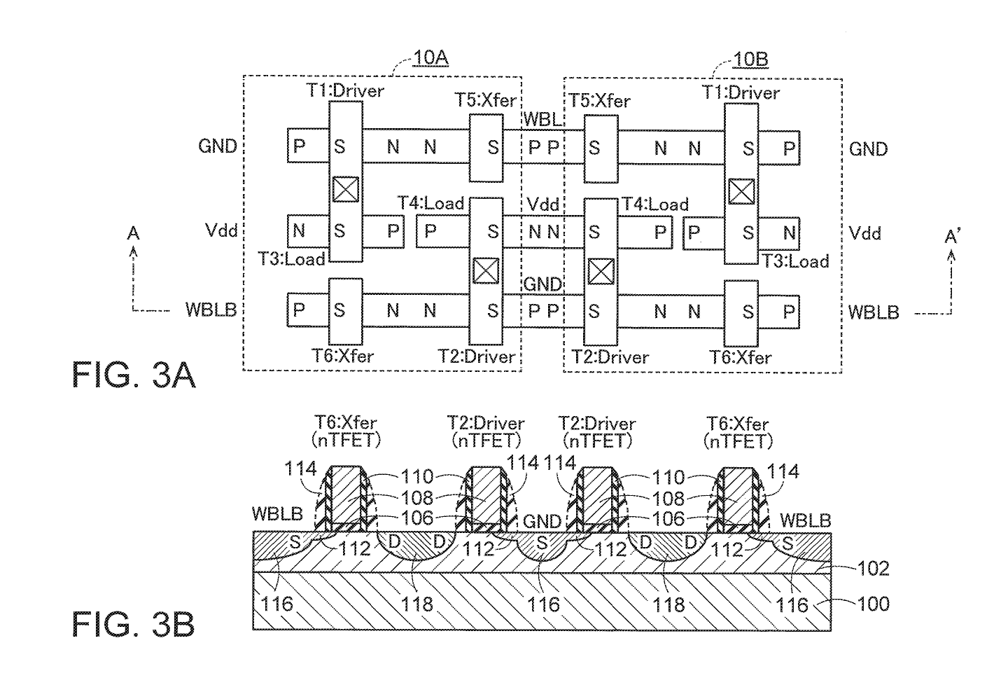

FIG. 3A is a layout chart of a design in which two memory cells 10 with the layout in FIG. 2 are arranged in parallel. Note that the data read circuit is omitted hereinafter in the layout chart and the cross-sectional view. FIG. 3B is a cross-sectional view taken along A-A′ in FIG. 3A. Memory cells 10A and 10B include a first region 100 such as an n-type well region and a second region 102 such as a p-type channel region. Though no particular problem seems to occur only in FIG. 3A, the source region of the transfer transistor T6 of the memory cell 10A, the source region of the driver transistor T2 of the memory cell 10A, and the second region 102 are of the same p-type conductive layers in FIG. 3B, so that the source region of the transfer transistor T6 and the source region of the driver transistor T2 of the memory cell 10A short-circuit in the second region 102. Therefore, it is difficult to configure the memory cell 10 according to this embodiment by such a design.

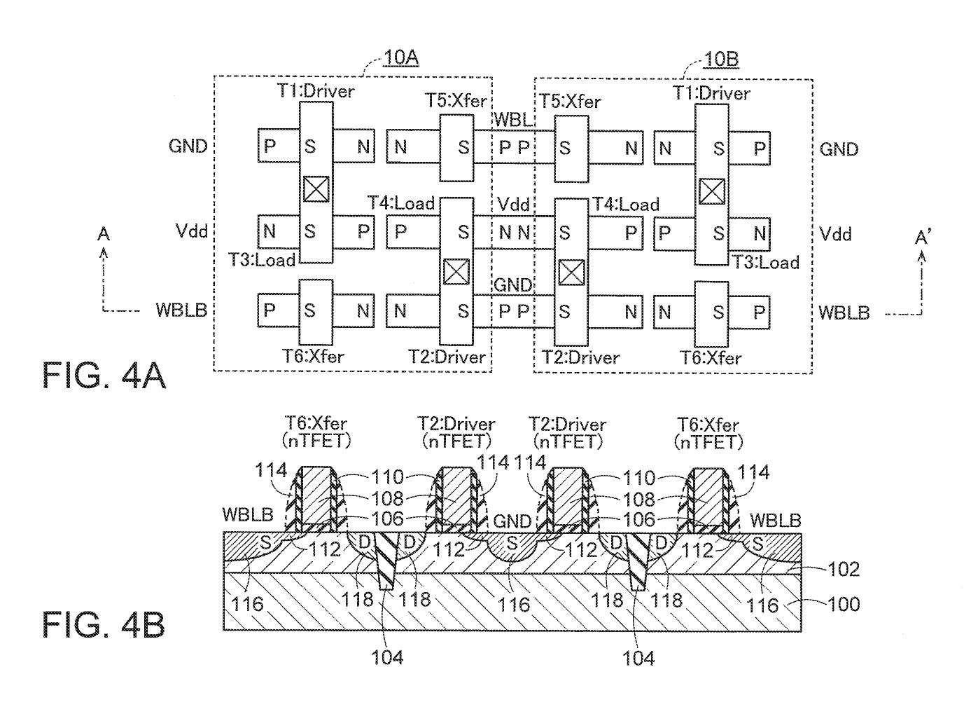

Hence, as illustrated in FIG. 4A, an insulating film for isolating an element is provided between the driver transistor T1 and the transfer transistor T5 and between the driver transistor T2 and the transfer transistor T6 to thereby physically divide the n-type second region 102. FIG. 4B is a cross-sectional view taken along A-A′ in FIG. 4A. Since other active regions have the same configuration and process, the cross-sectional view taken along A-A′ will be described as an example.

As illustrated in FIG. 4B, the active region is formed by the first region 100, the second region 102, and element isolation insulating films 104, in which the transfer transistors T6 and the driver transistors T2 are formed on the second region 102. The first region 100 is an n-type conductive layer. On the first region 100, the second region of the p-type conductive layer is formed. The element isolation insulating film 104 is formed by STI (Shallow Trench Isolation) and divides a junction surface between the first region and the second region to divide the second region from the second region of another transistor.

The transfer transistor T6 is an nTFET formed on the second region 102, and includes a gate insulating film 106, a gate electrode 108, an offset spacer 110, a source side junction region 112, a gate side wall 114, a source region 116, and a drain region 118. In this embodiment, both of the driver transistor T2 and the transfer transistor T6 are nTFETs, and therefore the above-described configuration also applies to the driver transistor T2. Besides, the driver transistor 12 and the transfer transistor T6 are formed such that the respective n-type drain regions 118 are adjacent to each other via the element isolation insulating film 104.

The gate insulating film 106 is an insulating film existing between the gate and the second region in the FET. The gate electrode 108 is an electrode to which voltage is applied to turn on/off the gate of the FET, and the current between source and drain terminals is controlled by applying voltage to the gate electrode 108. The offset spacer 110 and the gate side wall 114 form a side wall at the gate electrode 108. The source side junction region 112 is a diffusion layer formed to be shallow from the source region in order to form a tunnel junction between a p-type semiconductor and an n-type semiconductor.

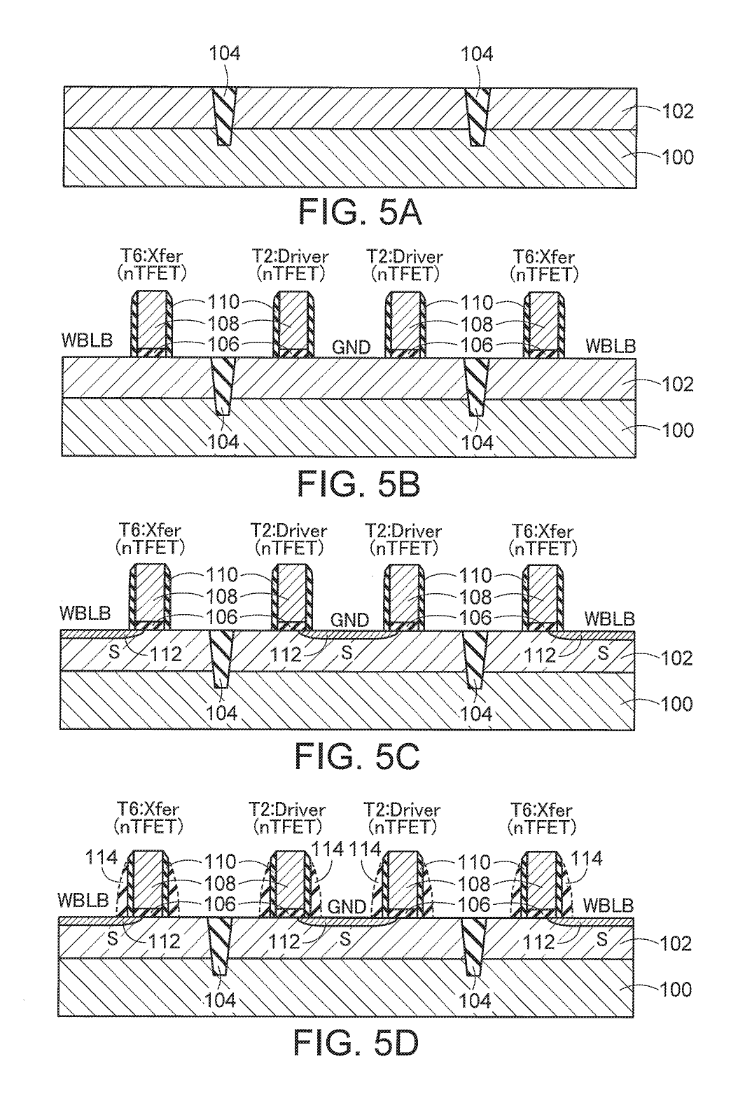

The above is the configuration of the nTFET, and the process will be described next. Here, a flow of forming the driver transistor T2 and the transfer transistor T6 will be described following its manufacturing processes while focusing on a cross-sectional structure in the cross-sectional view taken along A-A′ in FIG. 4A. Note that the load transistors T3, T4 made of pTFETs have the same basic configuration with only doping species changed, and therefore their description will be omitted. FIGS. 5A to 5D are views illustrating processes of the configurations of the transistors illustrated in FIG. 4B.

First, as illustrated in FIG. 5A, the element isolation insulating films 104 with a depth of 2000 to 3000 angstroms (Å) are formed by an embedded element isolation method on a p-type silicon substrate or an n-type silicon substrate. At an active element part, a not-illustrated oxide film of 100 angstroms (Å) or less is formed in the silicon surface, and then the first region 100 and the second region 102 are formed by ion implantation and activation RTA (Rapid Thermal Annealing) as illustrated in the drawing. A typical example of an ion implantation condition is a condition described below. The n-type first 100 is formed by implanting P ions with an acceleration energy of 500 key and a dose amount of 3.0 E 13 cm⁻², and the p-type second region 102 is formed by implanting B ions with an acceleration energy of 10 keV and a dose amount of 1.0 E 14 cm⁻². In the regions of the load transistors T3, T4 made of pTFETs, the p-type first is formed by implanting B ions with an acceleration energy of 260 keV and a dose amount of 2.0 E 13 cm⁻², and the n-type channel is formed by implanting P ions with an acceleration energy of 10 key and a dose amount of 1.0 E 14 cm⁻².

Next, as illustrated in FIG. 5B, the gate electrodes 108 are deposited using polysilicon of 500 angstroms (Å) to 2000 angstroms (Å) via the gate insulating films 106 of 5 angstroms (Å) to 60 angstroms (Å) formed by a thermal oxidation method or an LPCVD (Low Pressure Chemical Vapor Deposition) method, and pre-doping is performed on the gate electrodes 108. At this time, doping of n-type is performed on the nTFETs. As a typical example of a condition of the n-type doping, the doping is performed by P ions with an acceleration energy of 5 keV and a dose amount of 5.0 E 15 cm⁻². Note that doping of p-type is performed on the pTFETs of the load transistors T3, T4, and the doping is performed under a doping condition of B ions with an acceleration energy of 2.5 keV and a dose amount of 5.0 E 14 cm⁻².

Next, gate patterning is performed by an optical lithography method, an X-ray lithography method, or an electron beam lithography method, and etching is performed on the gate electrodes 108 and the gate insulating films 106 by an RIE (Reactive Ion Etching) method to form gate electrodes. Here, the gate insulating films 106 are not limited to SiO₂ but is considered to be high dielectric layer films such as SiON, SiN, or HfSiON or the like. Further, it is also conceivable to form a metal film such as TiN under the polysilicon gate electrodes 108.

Next, as post-oxidation, post-oxidized SiO₂ is formed by a thermal oxidation method into 10 angstroms (521 ) to 20 angstroms (Å) (not illustrated), and then the offset spacers 110 are formed using SiO₂ or SiN by the LPCVD method into a thickness of 30 angstroms (Å) to 120 angstroms (Å).

Next, as illustrated in FIG. 5C, shallow diffusion layers are formed as the source side junction regions 112, to thereby form tunnel junctions in the source regions. For example, the source side junction regions 112 are formed by performing ion implantation of As ions with an acceleration energy of 40 keV and a dose amount of 3.0 E 13 cm⁻², and at a tilt of 30 degrees, as Halo condition, and then performing ion implantation of BF₂ ions or B ions with an acceleration energy of 1.0 to 3.0 keV and a dose amount of 5.0 E 14 cm ² to 1.5 E 15 cm ². Further, the source side junction regions of the pTFETs are formed by forming n-type tunnel junctions, performing ion implantation of BF₂ with an acceleration energy of 20 key and a dose amount of 3.0 E 13 cm⁻², and at a tilt of 30 degrees as Halo condition, and then performing ion implantation of As ions with an acceleration energy of 1.0 to 3.0 keV and a dose amount of 5.0 E 14 cm⁻² to 1.5 E 15 cm⁻². Thereafter, activation RTA is performed. Note that in the TFETs, formation of the shallow diffusion layer on the drain side is not performed so as to suppress a GIDL (Gate induced drain leak) current on the drain side.

Next, as illustrated in FIG. 5D, the gate side walls 114 are formed using TEOS, SiN or a combination of TEOS and SIN. Subsequently, only the source regions of the nTFETs and the drain regions of the pTFETs (not illustrated) are opened with a resist, and p-type high-concentration diffusion layers 116 are formed by p+ doping. Further, only the drain regions of the nTFETs and the source regions of the pTFETs (not illustrated) are opened with a resist, and n-type high-concentration diffusion layers 118 are formed by n+ doping. More specifically, the p+ doping is performed by B ions with an acceleration energy of 2 keV and a dose amount of 2.0 E 15 cm⁻² to 4.0 E 15 cm⁻², and the n+ doping is performed by As ions with an acceleration energy of 10 keV and a dose amount of 2.0 E 15 cm⁻² to 4.0 E 15 cm⁻².

Next, the activation annealing is performed to form high-concentration diffusion layers in the source regions and the drain regions of the nTFETs and the pTFETs. Examples of a typical annealing condition include spike annealing at 1030° C. and so on. Through this process, a semiconductor as in the cross-sectional view in FIG. 4B is formed. Thereafter, for example, a Ni silicide layer is formed, and general formation of an interlayer film, a contact, metal wiring, passivation and so on is performed, whereby an SRAM using the TFETs is formed in which the driver transistor T2 and the transfer transistor T6 are physically divided by STI.

As described above, by the semiconductor device according to this embodiment, the driver transistor T2 and the transfer transistor T6 which are physically divided by the STI formed between their n-type drains are formed on the same active region, thereby making it possible to constitute the memory cell 10 of the SRAM using six TFETs. Using the TFETs for the data holding circuit can realize the SRAM that is lower in leak current and is driven with lower power consumption than before.

### Second Embodiment

In the above-described semiconductor device according to the first embodiment, constituting the SRAM using TFETs by physically dividing the drain regions of the nTFETs existing on the n-type second region has been described. In this embodiment, an SRAM is constituted by electrically dividing the second region using the source region shared between the nTFETs of two memory cells existing on the p-type second region. Hereinafter, portions different from the above-describe embodiment will be described in detail.

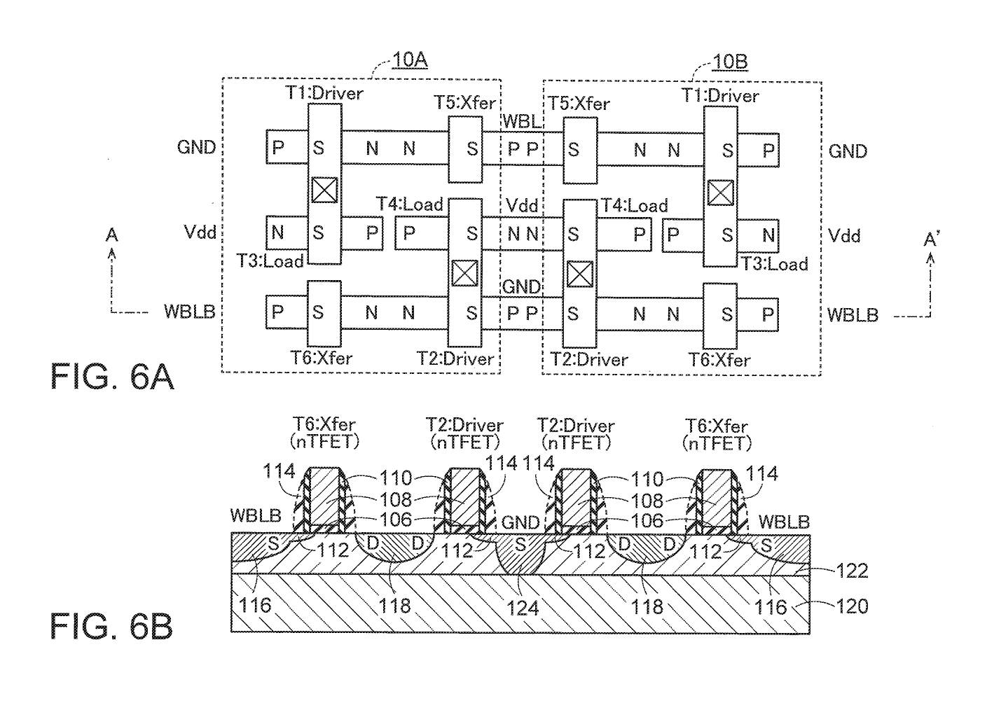

The configuration and the operation of the circuit are the same as those of the above-described first embodiment and therefore their detailed description will be omitted. FIG. 6A is a layout chart of two memory cells according to this embodiment. Unlike the first embodiment, the n-type drain region shared between two the transistors T2, T6 is not physically divided on the layout.

FIG. 6B is a cross-sectional view taken along A-A′ in FIG. 6A. The two memory cells include a first region 120 such as a well region or a substrate region of a p-type conductive layer, a second region 122 such as a channel region of an n-type conductive layer formed on the first region 120, transfer transistors 16 made of nTFETs formed on the second region 122, and driver transistors T2 made of nTFETs sharing the drain regions with the transfer transistors T6. The same symbols as those in FIG. 4B denote the same components. As illustrated in FIG. 6B, the configurations of the p-type first region 120, the n-type second region 122 and a source region 124 of the driver transistors T2 are the portions different from the above-described embodiment.

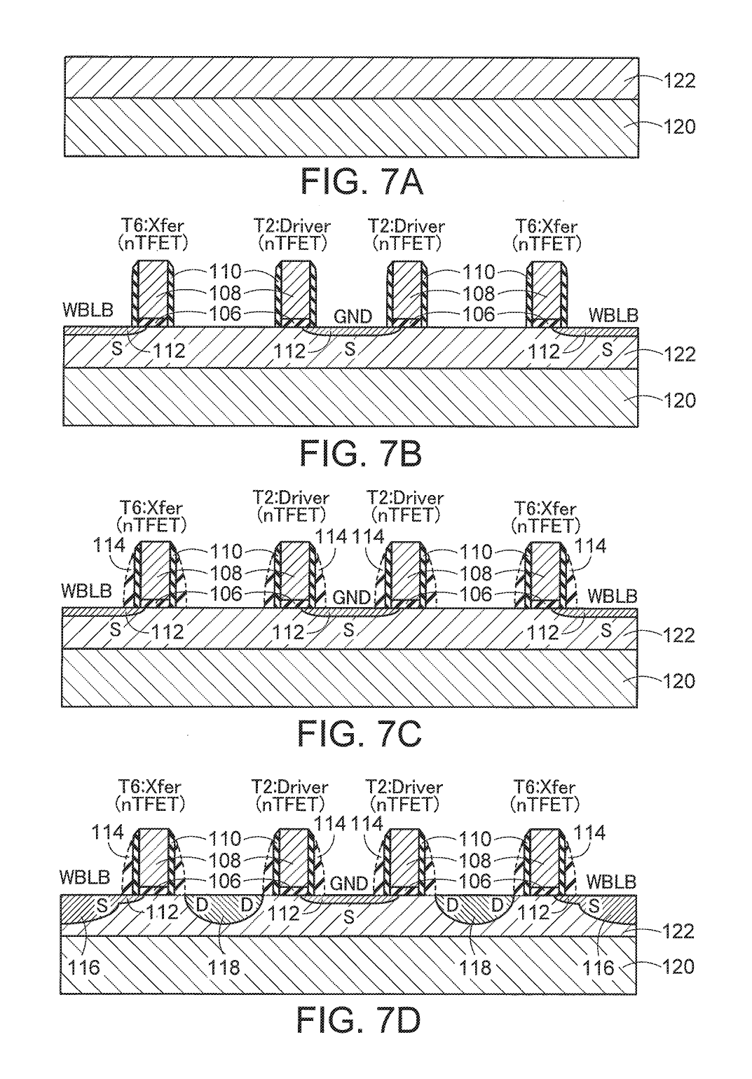

Since the n-type second region 122 formed on the p-type first region 120 constitutes the active region, the source regions 116, 124 formed of the p-type of the driver transistors T2 made of the nTFETs and the transfer transistors 16 made of the nTFETs never short-circuit in the second region. However, if the source region 124 of the driver transistors T2 does not reach the junction surface between the first region 120 and the second region 122, short-circuit occurs in the second region 122 because all of the drain region shared between the driver transistor T2 and the transfer transistor 16 of the memory cell 10A, the drain region shared between the driver transistor T2 and the transfer transistor T6 of the memory cell 10B, and the second region 122 are the n-type. Hence, in the configuration illustrated in FIG. 6B, the second region 122 is electrically divided by the p-type source region 124 to prevent short circuit in the second region 122. Hereinafter, processes will be described using FIGS. 7.

FIGS. 7A to 7D are views illustrating the processes for forming the configuration in FIG. 6B. Here, a flow of forming the driver transistors T2 and the transfer transistors 16 will be described following its manufacturing processes while focusing on a cross-sectional structure in the cross-sectional view taken along A-A′ in FIG. 6A. Similarly to the above-described first embodiment, pTFETs forming the load transistors T3, T4 have the same basic configuration with only doping species changed.

First, as illustrated in FIG. 7A, an element isolation insulating film with a depth of 2000 angstroms (Å) to 3000 angstroms (Å) by an embedded element isolation method on a p-type silicon substrate or an n-type silicon substrate. Note that the STI is not formed in the active region in this embodiment and therefor is not illustrated. At an active element part, a not-illustrated oxide him of 100 angstroms (Å) or less is formed on the silicon surface, and then the p-type first region 120 and the n-type second region 122 are formed by ion implantation and activation RTA. As a typical example of an ion implantation condition, the p-type first is formed by implanting B ions with an acceleration energy of 260 key and a dose amount of 2.0 E 13 cm⁻², and the n-type second is formed by implanting P ions with an acceleration energy of 10 keV and a dose amount of 1.0 E 14 cm⁻². Hereinafter, formation until FIG. 7C is performed similarly to the formation until FIG. 5D.

Next, as illustrated in FIG. 7D, the gate side walls 114 are formed and then only the source regions of the transfer transistors T6 made of the nTFETs and the drain regions of the load transistors T3, T4 made of the not-illustrated pTFETs are opened with a resist, and p-type high-concentration diffusion layers 116 are formed by p+ doping. Further, the drain regions of the driver transistors T2 and the transfer transistors T6 made of the nTFETs and the source regions of the load transistors T3, T4 made of the pTFETs are opened with a resist, and n-type high-concentration diffusion layers 118 are formed by n+ doping. More specifically, the p+ doping is performed by ion implantation of B ions with an acceleration energy of 2 keV and a dose amount of 2.0 E 15 cm⁻² to 4.0 E 15 cm⁻², and the n+ doping is performed by ion implantation of As ions with an acceleration energy of 10 keV and a dose amount of 2.0 E 15 cm⁻² to 4.0 E 15 cm⁻².

Next, the source region of the driver transistors T2, namely, only a GND region is opened with a resist, and a p-type high-concentration diffusion layer 124 is formed. Here, the GND region is formed deeper than the junction surface between the second region 122 and the first region 120, thereby electrically dividing the nodes. More specifically, the p+ doping is performed by ion implantation of B ions with an acceleration energy of 5 keV and a dose amount of 2.0 E 15 cm⁻² to 4.0 E 15 cm ⁻².

Next, the activation annealing is performed to form high-concentration diffusion layers in the source regions and the drain regions of the nTFETs and the pTFETs. Examples of a typical annealing condition include spike annealing at 1030° C. and so on. Through this process, a semiconductor as in the cross-sectional view in FIG. 6B is formed. Thereafter, for example, a Ni suicide layer is formed, and general formation of an interlayer film, a contact, metal wiring, passivation and so on is performed, whereby an SRAM using the TFETs is formed in which the driver transistor T2 and the transfer transistor T6 are electrically divided by the GND 124 formed deep to reach the first region 120.

As described above, by the semiconductor device according to this embodiment, the p-type source region of the driver transistors are formed deep to reach the p-type first region 120, thereby making it possible to electrically divide the second region 122 of the transistors of the memory cell 10A and the n-type second region 122 of the transistors of the memory cell 10B. Thus, the transistors of the two memory cells 10A, 10B are formed on the same active region, thereby making it possible to constitute the memory cell 10 of the SRAM using six TFETs.

### Third Embodiment

In the semiconductor device according to the above-described second embodiment, both of the driver transistors and the transfer transistors are made of the nTFETs. In the third embodiment, while the driver transistors are made of nTFETs as in the second embodiment, the transfer transistors will be made of pTFETs. Hereinafter, portions different from the above-describe embodiments will be described in detail.

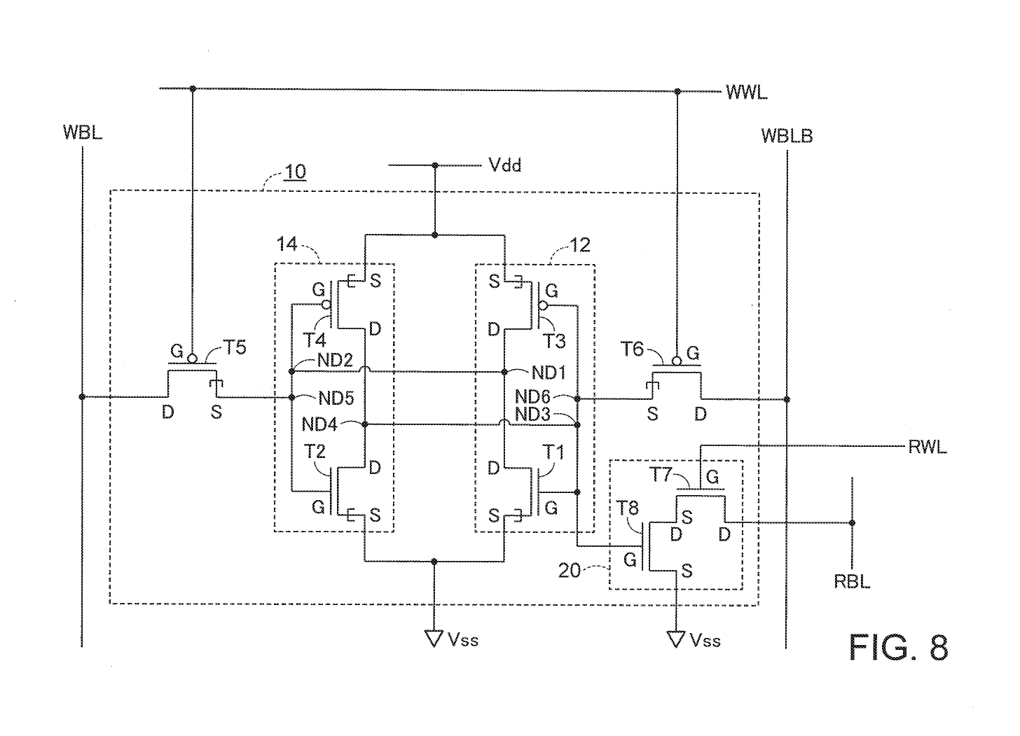

FIG. 8 is a circuit diagram illustrating a memory cell 10 according to this embodiment. The memory cell 10 has the same basic configuration as that of the memory cell 10 illustrated in FIG. 1, but is different in that the transfer transistors T5, T6 are made of the pTFETs. More specifically, the transfer transistor T5 has a gate connected to a write word line WWL that applies voltage for turning on the transfer transistors T5, T6 and a drain connected to a bit line WBL that applies voltage for storing a state to driver transistors T1, T2. Then, the driver transistors T1, T2 store states by the voltages applied to the gate and drain of the transfer transistor T5. This also applies to the transfer transistor T6.

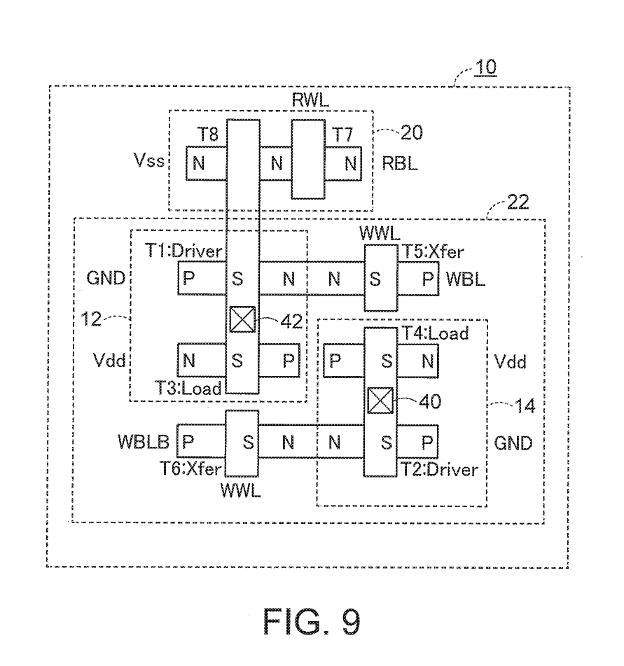

FIG. 9 is a chart illustrating a layout of the memory cell 10 according to this embodiment. When the transfer transistors T5, T6 are made of the pTFETs, it becomes possible that the drain regions of the driver transistors T1, T2 and the source regions of the transfer transistors T5, T6 are shared respectively as illustrated in FIG. 9. Such a configuration is enabled by constituting the transistors using TFETs whose source regions and drain regions are formed of different type conductive layers. Similarly to the circuit diagram, the layout is also the same as the layout chart illustrated in FIG. 2 except that the transfer transistors T5, T6 are the pTFETs, and its detailed description will be omitted.

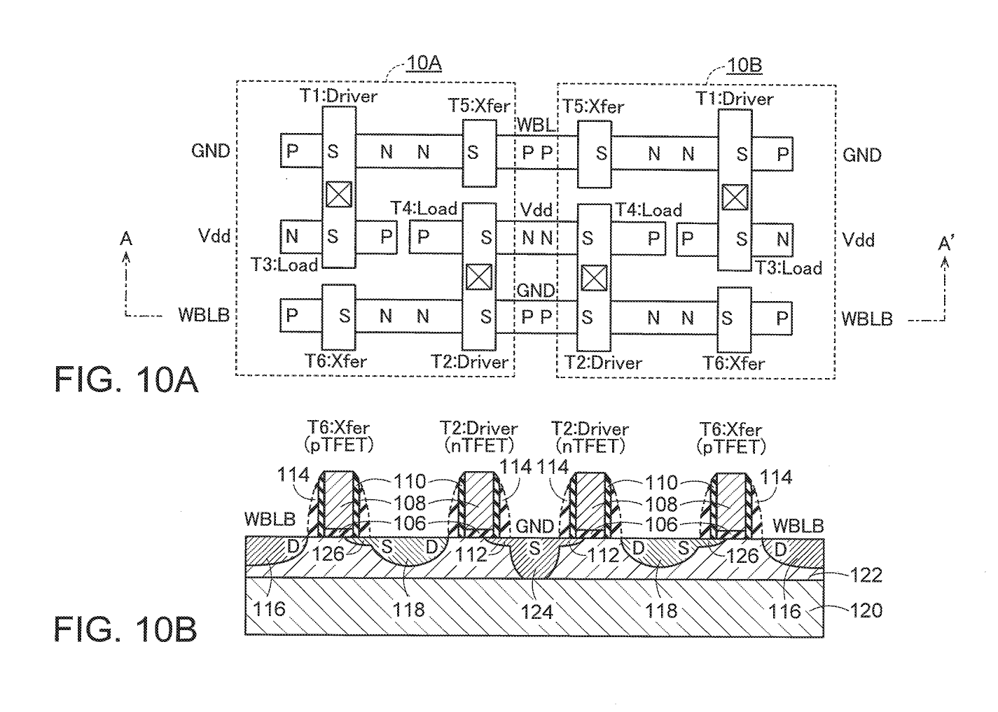

FIG. 10A is a layout chart in which the memory cells 10 illustrated in FIG. 9 are arranged side by side. The difference from FIG. 6A is that the source regions and the drain regions of the transfer transistors T5, T6 are replaced with each other. FIG. 10B is a cross-sectional view taken along A-A′ in FIG. 10A. As illustrated in FIG. 10B, the portion shared between the n-type drain region of the driver transistor T2 and the n-type source region of the transfer transistor T6 on the n-type second region in each of the memory cells 10A, 10B is the portion different from the above-described second embodiment.

More specifically, the semiconductor device according to this embodiment includes a first region 120 such as a well region or a substrate region of a p-type conductive layer, a second region 122 such as a channel region of an n-type conductive layer formed on the first region 120, transfer transistors T6 made of the nTFETs formed on the second region 122, and driver transistors T2 made of the pTFETs having the source regions shared with the drain regions of the transfer transistors T6. As in the second embodiment, the regions of the n-type conductive layers shared between drain regions of the driver transistors T2 and the source regions of the transfer transistors T6 of the two memory cells 10A, 10B are not physically divided on the layout. Note that in FIG. 10B, the same symbols as those in FIG. 4B and FIG. 6B denote the same components. The configuration for preventing short circuit by a source region 124 between the memory cells 10A and 10B is the same as in the second embodiment.

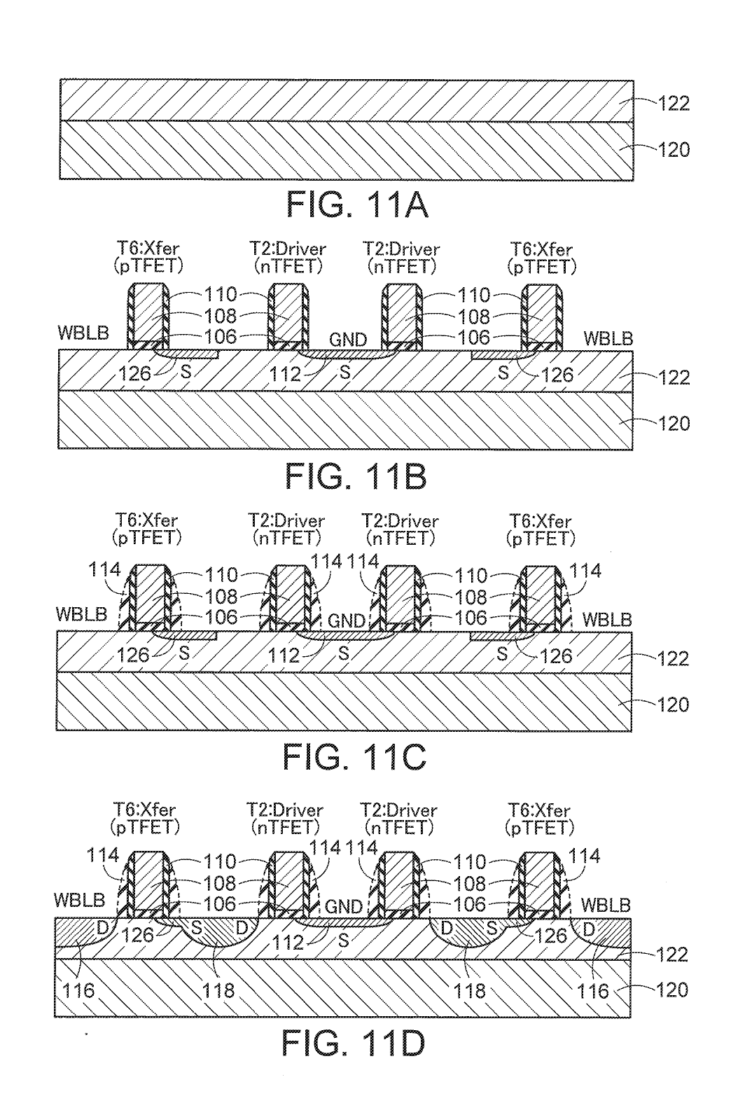

Hereinafter, processes will be described using FIG. 11. FIGS. 11A to 11D are views illustrating the processes for forming the configuration in FIG. 10B. Here, a flow of forming the driver transistors T2 and the transfer transistors T6 will be described following its manufacturing processes while focusing on a cross-sectional structure in the cross-sectional view taken along A-A′ in FIG. 10A. Similarly to the above-described first embodiment, pTFETs forming the load transistors T3, T4 have the same basic configuration with only doping species changed.

First, as illustrated in FIG. 11A, an element isolation insulating film with a depth of 2000 angstroms (Å) to 3000 angstroms (Å) by an embedded element isolation method on a p-type silicon substrate or an n-type silicon substrate. Note that the STI is not formed in the active region in this embodiment and therefor is not illustrated. At an active element part, a not-illustrated oxide film of 100 angstroms (Å) or less is formed on the silicon surface, and then the p-type first region 120 and the n-type second region 122 are formed by ion implantation and activation RTA. As a typical example of an ion implantation condition, the p-type first is formed by implanting B ions with an acceleration energy of 260 key and a dose amount of 2.0 E 13 cm⁻², and the n-type second is formed by implanting P ions with an acceleration energy of 10 keV and a dose amount of 1.0 E 14 cm⁻². Hereinafter, formation until an offset spacer 110 is performed similarly to the formation until FIG. 5B.

Next, as illustrated in FIG. 11B, shallow diffusion layers are formed as source side junction regions 112, 126 to thereby form tunnel junctions in the source regions of the nTFETs and pTFETs. For example, the source side junction region 112 of the nTFETs is formed by performing ion implantation of As ions with an acceleration energy of 40 keV and a dose amount of 3M E 13 cm⁻², and at a tilt of 30 degrees, as Halo condition, and then performing ion implantation of BF₂ ions or B ions with an acceleration energy of 1.0 to 3.0 keV and a dose amount of 5.0 E 14 cm⁻² to 1.5 E 15 cm². Further, the source side junction regions 126 of the pTFETs are formed by forming n-type tunnel junctions, performing ion implantation of BF₂ ions with an acceleration energy of 20 keV and a dose amount of 3.0 E 13 cm⁻², and at a tilt of 30 degrees as Halo condition, and then performing ion implantation of As ions with an acceleration energy of 1.0 to 3.0 keV and a dose amount of 5.0 E 14 cm⁻² to 1.5 E 15 cm⁻². Thereafter, activation RTA is performed. Note that in the TFETs, formation of the shallow diffusion layer on the drain side is not performed so as to suppress a GIDL current on the drain side.

Next, as illustrated in FIG. 11C, gate side walls 108 are formed by the same process as in the above-described embodiment. Subsequently, as illustrated in FIG. 11D, the drain regions of the transfer transistors T6 made of the pTFETs are opened with a resist, and p-type high-concentration diffusion layers 116 are formed by p+ doping. Further, only the drain regions of the nTFET and the source regions of the pTFET are opened with a resist, and n-type high-concentration drain regions 118 are formed by n+ doping. More specifically, the p+ doping is performed by ion implantation of B ions with an acceleration energy of 2 keV and a dose amount of 2.0 E 15 cm⁻² to 4.0 E 15 cm⁻², and the n+ doping is performed by ion implantation of As ions with an acceleration energy of 10 keV and a dose amount of 2.0 E 15 cm⁻² to 4.0 E 15 cm⁻².

Next, the source region of the driver transistors T2, namely, only a GND region is opened with a resist, and a p-type high-concentration diffusion layer 124 is formed. Here, the GND region is formed deeper than the junction surface between the second region 122 and the first region 120, thereby electrically dividing the nodes. More specifically, the p+ doping is performed by B ions with an acceleration energy of 5 keV and a dose amount of 2.0 E 15 cm⁻² to 4.0 E 15 cm⁻².

Next, the activation annealing is performed to form high-concentration diffusion layers in the source regions and the drain regions of the nTFETs and the pTFETs. Examples of a typical annealing condition include spike annealing at 1030° C. and so on. Through this process, a semiconductor as in the cross-sectional view in FIG. 10B is formed. Thereafter, for example, a Ni silicide layer is formed, and general formation of an interlayer film, a contact, metal wiring, passivation and so on is performed, whereby an SRAM using the TFETs is formed in which the driver transistor T2 and the transfer transistor T6 are electrically divided by the GND 124 formed deep to reach the first region 120.

As described above, even by the semiconductor device according to this embodiment, the p-type source region of the driver transistors are formed deep to reach the p-type first region 120, thereby making it possible to electrically divide the second region 122 of the transistors of the memory cell 10A and the n-type second region 122 of the transistors of the memory cell 10B. Thus, the transistors of the two memory cells 10A, 10B are formed on the same active region, thereby making it possible to constitute the memory cell 10 of the SRAM using six TFETs.

Note that though the driver transistor T2 and the transfer transistor T6 have been mainly described in the above-described embodiments, the driver transistor Ti and the transfer transistor T5 are also similarly formed, Further, the doping condition described in each of the above-described embodiments is illustrated as one example, and formation is performed using other doping conditions does not depart from the spirit of the present invention.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device, comprising:
a first region of an n-type conductive layer;
a second region of a p-type conductive layer on the first region;
a first TFET having an n-type drain region formed in the second region;
a second TFET having an n-type drain region formed in the second region, and provided adjacent to the first TFET; and
an insulating film between the drain region of the first TFET and the drain region of the second TFET, and reaching the first region.

2. The semiconductor device according to claim 1, further comprising:
a third TFET sharing a source region with the second TFET, and having an n-type drain region formed in the second region;
a fourth TFET having an n-type drain region formed in the second region, and provided adjacent to the third TFET; and
another insulating film between the drain region of the third TFET and the drain region of the fourth TFET, and reaching the first region.

3. The semiconductor device according to claim 1,
wherein the first TFET comprises a gate connected to a word line that applies voltage for turning on the first TFET, and a source connected to a bit line that applies voltage for storing a state to the second TFET, and
wherein the second TFET stores a state of the voltage applied to the bit line when the first TFET is turned on.

4. The semiconductor device according to claim 1,
wherein the insulating film divides a junction surface between the first region and the second region.

5. The semiconductor device according to claim 1,
wherein the insulating film is an element isolation region that divides the second region from a second region of another TFET.

6. The semiconductor device according to claim 1,
wherein the second TFET is one of driver transistors of an inverter circuit being a data holding unit of an SRAM.

7. The semiconductor device according to claim 6, further comprising:
a first nMOSFET having a gate connected to a gate of the second TFET, and a source grounded; and
a second nMOSFET configured to have a gate connected to a word line that applies voltage for reading data in the data holding unit of the SRAM, a source connected to a drain of the first nMOSFET, and a drain connected to a bit line that reads the data in the data holding unit of the SRAM.

8. A semiconductor device, comprising:
a first region of a p-type conductive layer;
a second region of an n-type conductive layer on the first region;
a first TFET having an n-type drain region formed in the second region; and
a second TFET sharing the drain region with the first TFET, and having a p-type source region, the source region reaching a junction surface between the first region and the second region.

9. The semiconductor device according to claim 8,
wherein the first TFET has a gate connected to a word line that applies voltage for turning on the first TFET, and a source connected to a bit line that applies voltage for storing a state to the second TFET, and
wherein the second TFET stores a state of the voltage applied to the bit line when the first TFET is turned on.

10. The semiconductor device according to claim 8,
wherein the source region of the second TFET is a p-type diffusion layer higher in concentration than the second region.

11. The semiconductor device according to claim 8,
wherein the source region of the second TFET divides the second region.

12. The semiconductor device according to claim 8,
wherein the second TFET is one of driver transistors of an inverter circuit being a data holding unit of an SRAM.

13. The semiconductor device according Lo claim 12, further comprising:
a first nMOSFET having a gate connected to a gate of the second TFET, and a source grounded; and
a second nMOSFET configured to have a gate connected to a word line that applies voltage for reading data in the data holding unit of the SRAM, a source connected to a drain of the first nMOSFET, and a drain connected to a bit line that reads the data in the data holding unit of the SRAM.

14. A semiconductor device, comprising:
a first region of a p-type conductive layer;
a second region of an n-type conductive layer on the first region;
a first TFET having an n-type source region formed in the second region; and
a second TFET sharing an n-type drain region with the source region of the first TFET, and having a p-type source region, the source region reaching a junction surface between the first region and the second region.

15. The semiconductor device according to claim 14,
wherein the first TFET has a gate connected to a word line that applies voltage for turning on the first TFET, and a drain connected to a bit line that applies voltage for storing a state to the second TFET, and
wherein the second TFET stores a state of the voltage applied to the bit line when the first TFET is turned on.

16. The semiconductor device according to claim 14,
wherein the source region of the second TFET is a p-type diffusion layer higher in concentration than the second region.

17. The semiconductor device according to claim 14,
wherein the source region of the second TFET divides the second region.

18. The semiconductor device according to claim 14,
wherein the second TFET is one of driver transistors of an inverter circuit being a data holding unit of an SRAM.

19. The semiconductor device according to claim 18, further comprising:
a first nMOSFET having a gate connected to a gate of the second TFET, and a source grounded; and
a second nMOSFET having a gate connected to a word line that applies voltage for reading data in the data holding unit of the SRAM, a source connected to a drain of the first nMOSFET, and a drain connected to a bit line that reads the data in the data holding unit of the SRAM.
